(19) United States
(12) Patent Application Publication
(10) Pub. No.: US 2024/0304492 A1
(43) Pub. Date: Sep. 12, 2024

(54) BACK SIDE DESIGN FOR FLAT SILICON CARBIDE SUSCEPTOR

(71) Applicant: Applied Materials, Inc., Santa Clara, CA (US)

(72) Inventors: Hui CHEN, Tempe, AZ (US); Xinning LUAN, Tempe, AZ (US); Kirk Allen FISHER, Tempe, AZ (US); Shawn Joseph BONHAM, Mesa, AZ (US); Aimee S. ERHARDT, Tempe, AZ (US); Zhepeng CONG, San Jose, CA (US); Shaofeng CHEN, Austin, TX (US); Schubert S. CHU, San Francisco, CA (US); James M. AMOS, Apache Junction, AZ (US); Philip Michael AMOS, Apache Junction, AZ (US); John NEWMAN, Chandler, AZ (US)

(21) Appl. No.: 18/667,082

(22) Filed: May 17, 2024

Related U.S. Application Data
(63) Continuation of application No. 17/191,786, filed on Mar. 4, 2021.
(60) Provisional application No. 63/085,528, filed on Sep. 30, 2020.
(60) Provisional application No. 63/076,786, filed on Sep. 10, 2020.

(51) Int. Cl. H01L 21/687; C23C 16/32; C23C 16/458

(52) U.S. Cl. CPC H01L 21/68757; C23C 16/325; C23C 16/4583

(57) ABSTRACT

A susceptor for use in a processing chamber for supporting a wafer includes a susceptor substrate having a front side and a back side opposite the front side, and a coating layer deposited on the susceptor substrate. The front side has a pocket configured to hold a wafer to be processed in a processing chamber, the pocket being textured with a first pattern. The back side is textured with a second pattern.

### CROSS-REFERENCE TO RELATED APPLICATIONS

This application is a continuation application of U.S. patent application Ser. No. 17/191,786, filed Mar. 4, 2021, which claims priority to U.S. Provisional Patent Application Ser. No. 63/076,786, filed Sep. 10, 2020, and U.S. Provisional Patent Application Ser. No. 63/085,528, filed Sep. 30, 2020, each of which are herein incorporated by reference.

### BACKGROUND

### Field

Examples described herein generally relate a susceptor to be used in semiconductor wafer processing, and more particularly to a silicon carbide coated susceptor having a back side thereof textured to be used in an epitaxy deposition process.

### Description of the Related Art

A chemical vapor deposition (CVD) process is used in semiconductor wafer processing, along with other processes, for epitaxially depositing a thin layer (generally, less than 10 micron) on a wafer. The CVD process requires a wafer held in a susceptor be heated up to an elevated temperature, for example, about 1200° C. The wafer is typically heated from room temperature to the elevated temperature within approximately 30 minutes. For a high quality epitaxy deposition, the susceptor needs to be produced to have precise dimensions and maintain its shape, especially flatness, during repeated rapid heating processes and cooling processes. That is, the susceptor is required to have excellent thermal shock resistance, high mechanical strength, and high thermal stability. Furthermore, the material of the susceptor needs to be impervious to gas and not outgas such that the susceptor acts as a barrier to contaminants released from both the susceptor and the outside environment in a CVD chamber. Examples of such material include silicon carbide (SiC), and thus the susceptor is typically made of a graphite substrate, having a front side with a pocket for holding a wafer therewithin and a back side with a flat and planar surface, coated with silicon carbide (SiC) by a CVD process. However, a typical SiC coated graphite susceptor is known to have warpage and bowing caused during a CVD process. Such warpage and bowing are induced by interfacial stress between the graphite substrate and the SiC coating layer due to a coefficient of thermal expansion (CTE) mismatch and the design difference between the front side and the back side of the susceptor. The interfacial stress is further increased by recent requirements in semiconductor wafer processing, such as an increased size of the susceptor for processing a larger sized wafer, an increased thickness ratio of the SiC coating layer and the graphite substrate for a lightweight and durable susceptor, and a sophisticated design of the pocket on the front side of the susceptor.

Therefore, there is need for a susceptor that is able to alleviate warpage and bowing while meeting the requirements of the size, weight, and designs.

### SUMMARY

Embodiments of the disclosure include a susceptor for use in a processing chamber for supporting a wafer. The susceptor includes a susceptor substrate having a front side and a back side opposite the front side, and a coating layer deposited on the susceptor substrate. The front side has a pocket configured to hold a wafer to be processed in a processing chamber, the pocket being textured with a first pattern, and the back side is textured with a second pattern.

Embodiments of the disclosure also include a processing chamber. The processing chamber includes a chamber body in fluid communication with one or more gas sources, a substrate support assembly including a susceptor. The susceptor includes a susceptor substrate having a front side and a back side opposite the front side, and a coating layer deposited on the susceptor substrate. The front side has a pocket configured to hold a wafer to be processed in a processing chamber, the pocket being textured with a first pattern, and the back side is textured with a second pattern.

Embodiments of the disclosure further include a method for manufacturing a susceptor for use in a processing chamber for supporting a wafer. The method includes forming a susceptor substrate having a front side and a back side opposite the front side, forming a pocket configured to hold a wafer to be processed in a processing chamber, texturing the pocket with a first pattern, texturing the back side with a second pattern, and forming a coating layer on the susceptor substrate.

### BRIEF DESCRIPTION OF THE DRAWINGS

So that the manner in which the above recited features of the present disclosure can be understood in detail, a more particular description, briefly summarized above, may be had by reference to examples, some of which are illustrated in the appended drawings. It is to be noted, however, that the appended drawings illustrate only some examples and are therefore not to be considered limiting of the scope of this disclosure, for the disclosure may admit to other equally effective examples.

FIG. 1 is a schematic top-view diagram of an example multi-chamber processing system according to some examples of the present disclosure.

FIG. 2 is a cross-sectional view of a thermal processing chamber that may be used to perform epitaxial growth according to some examples of the present disclosure.

FIGS. 3A and 3B are a cross-sectional view scanning electron Microscope (SEM) image and a top view SEM image of a susceptor according to one embodiment.

FIG. 4 is a flow diagram of a method that may be utilized to manufacture a susceptor according to one embodiment.

FIGS. 5A, 5B, and 5C are schematic cross-sectional views of a portion of a susceptor 500 according to one embodiment.

FIGS. 6A, 6B, 6C, and 6D are an isometric view, a front view, an enlarged front view, and a back view of a susceptor according to one embodiment.

FIGS. 7A, 7B, 7C, 7D, 7E, 7F, and 7G illustrate various patterns that may be applied to a back side of a susceptor according to one embodiment.

To facilitate understanding, identical reference numerals have been used, wherever possible, to designate identical elements that are common to the figures.

### DETAILED DESCRIPTION

Generally, examples described herein relate to a susceptor to hold a wafer thereon for semiconductor wafer processing, and more particularly to a silicon carbide coated susceptor having a back side thereof textured to be used in an epitaxy deposition process. Due to the textures on the back side of the susceptor, interfacial stress between a susceptor substrate and a coating layer is reduced during an epitaxy deposition process, reducing warping and bowing of the susceptor and increasing the flatness of the susceptor.

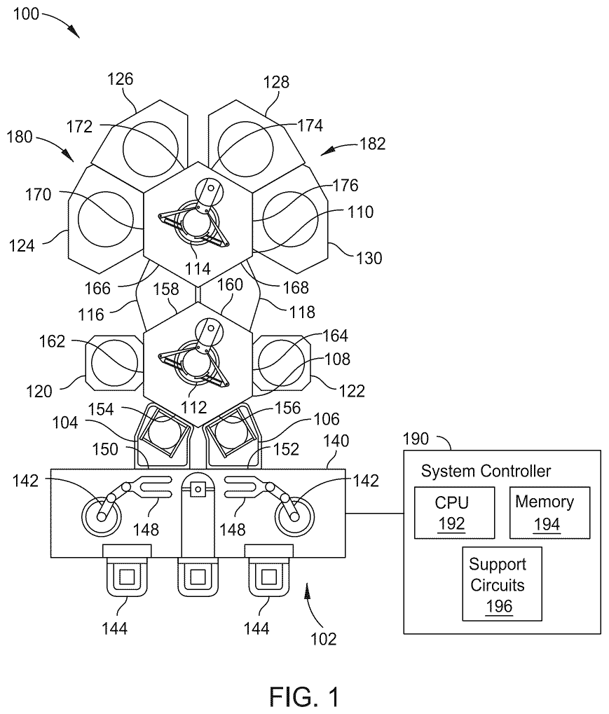

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough; otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process; the processing chamber 120 can be capable of performing an etch process; and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

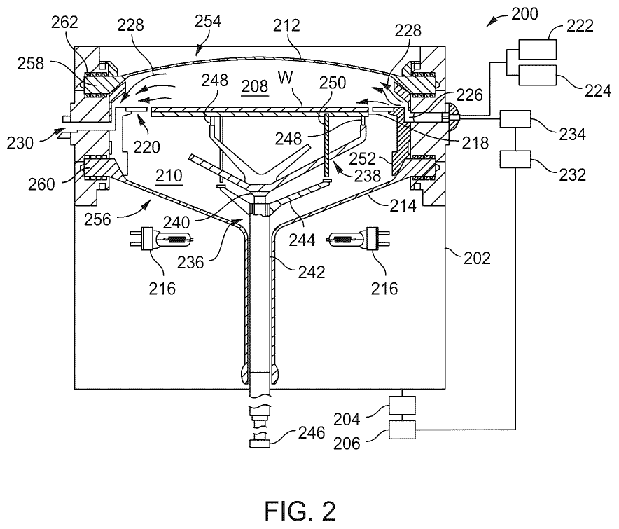

FIG. 2 is a cross-sectional view of a processing chamber 200 that may be used to perform epitaxial growth. The processing chamber 200 may be any one of processing chambers 120, 122, 124, 126, 128, 130 from FIG. 1. Non-limiting examples of the suitable processing chambers that may be modified according to embodiments disclosed herein may include the RP EPI reactor, Elvis chamber, and Lennon chamber, which are all commercially available from Applied Materials, Inc. of Santa Clara, Calif. The processing chambers 200 may be added to a CENTURA® integrated processing system available from Applied Materials, Inc., of Santa Clara, Calif. While the processing chamber 200 is described below to be utilized to practice various embodiments described herein, other semiconductor processing chambers from different manufacturers may also be used to practice the embodiment described in this disclosure.

The processing chamber 200 includes a chamber body 202, a support system 204, and a controller 206. The chamber body 202 includes an upper portion 208 and a lower portion 210. The upper portion 208 includes the area within the chamber body 202 between an upper dome 212 and a wafer W. The lower portion 210 includes the area within the chamber body 202 between a lower dome 214 and the bottom of the wafer W. Deposition processes generally occur on the upper surface of the wafer W within the upper portion 208.

The support system 204 includes components used to execute and monitor pre-determined processes, such as the growth of epitaxial films in the processing chamber 200. A controller 206 is coupled to the support system 204 and is adapted to control the processing chamber 200 and support system 204. The controller 206 may be the system controller 190 or a controller controlled by the system controller 190 for controlling processes within the processing chamber 200.

The processing chamber 200 includes a plurality of heat sources, such as lamps 216, which are adapted to provide thermal energy to components positioned within the processing chamber 200. For example, the lamps 216 may be adapted to provide thermal energy to the wafer W, a susceptor 218, and/or a preheat ring 220. The lower dome 214 may be formed from an optically transparent material, such as quartz, to facilitate the passage of thermal radiation therethrough. It is contemplated that lamps 216 may be positioned to provide thermal energy through the upper dome 212 as well as the lower dome 214.

The chamber body 202 includes a plurality of plenums formed therein. The plenums are in fluid communication with one or more gas sources 222, such as a carrier gas, and one or more precursor sources 224, such as deposition gases and dopant gases. For example, a first plenum 226 may be adapted to provide a deposition gas 228 therethrough into the upper portion 208 of the chamber body 202, while a second plenum 230 may be adapted to exhaust the deposition gas 228 from the upper portion 208. In such a manner, the deposition gas 228 may flow parallel to an upper surface of the wafer W.

In cases where a liquid precursor is used, the processing chamber 200 may include a liquid vaporizer 232 in fluid communication with a liquid precursor source 234. The liquid vaporizer 232 is be used for vaporizing liquid precursors to be delivered to the processing chamber 200. While not shown, it is contemplated that the liquid precursor source 234 may include, for example, one or more ampules of precursor liquid and solvent liquid, a shut-off valve, and a liquid flow meter (LFM).

A substrate support assembly 236 is positioned in the lower portion 210 of the chamber body 202. The substrate support assembly 236 is illustrated supporting a wafer W in a processing position. The substrate support assembly 236 includes a susceptor support shaft 238 formed from an optically transparent material and the susceptor 218 supported by the susceptor support shaft 238. A shaft 240 of the susceptor support shaft 238 is positioned within a shroud 242 to which lift pin contacts 244 are coupled. The susceptor support shaft 238 is rotatable in order to facilitate the rotation of the wafer W during processing. Rotation of the susceptor support shaft 238 is facilitated by an actuator 246 coupled to the susceptor support shaft 238. The shroud 242 is generally fixed in position, and therefore, does not rotate during processing. Support pins 248 couple the susceptor support shaft 238 to the susceptor 218.

Lift pins 250 are disposed through openings (not labeled) formed in the susceptor support shaft 238. The lift pins 250 are vertically actuatable and are adapted to contact the underside of the substrate W to lift the substrate W from a processing position (as shown) to a substrate removal position.

The preheat ring 220 is removably disposed on a lower liner 252 that is coupled to the chamber body 202. The preheat ring 220 is disposed around the internal volume of the chamber body 202 and circumscribes the substrate W while the substrate W is in a processing position. The preheat ring 220 facilitates preheating of a process gas as the process gas enters the chamber body 202 through the first plenum 226 adjacent to the preheat ring 220.

A central window portion 254 of the upper dome 212 and a bottom portion 256 of the lower dome 214 may be formed from an optically transparent material such as quartz. A peripheral flange 258 of the upper dome 212, which engages the central window portion 254 around a circumference of the central window portion 254, a peripheral flange 260 of the lower dome 214, which engages the bottom portion 256 around a circumference of the bottom portion 256, may all be formed from an opaque quartz to protect O-rings 262 in proximity to the peripheral flanges from being directly exposed to the heat radiation. The peripheral flange 258 may be formed of an optically transparent material such as quartz.

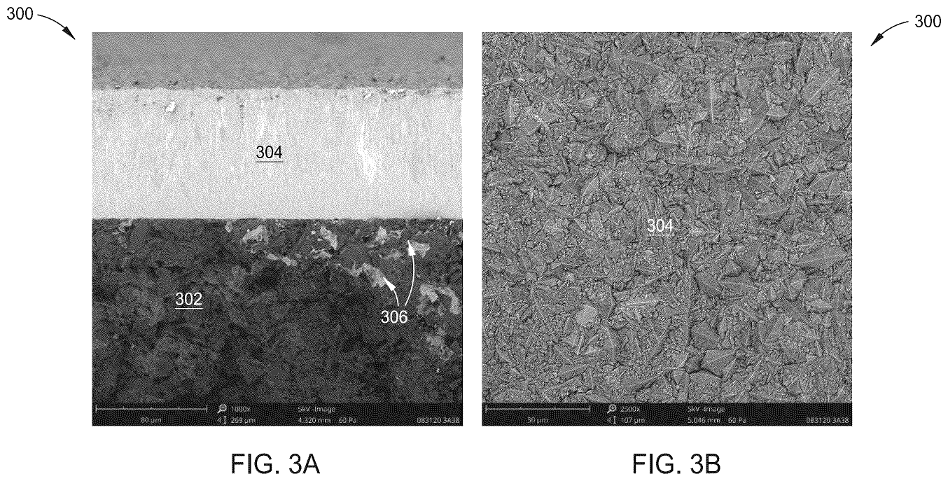

FIGS. 3A and 3B are a cross-sectional view scanning electron Microscope (SEM) image and a top view SEM image of a susceptor 300 according to one embodiment. The susceptor 300 may be the susceptor 218 disposed in the processing chamber 200 from FIG. 2. The susceptor 300 includes a susceptor substrate 302 and a coating layer 304. The susceptor substrate 302 is formed of graphite. The coating layer 304 is formed of silicon carbide (SiC). The graphite substrate 302 may be porous having pores 306, into which silicon carbide (SiC) tendrils are formed. This formation of silicon carbide (SiC) provides improved mechanical properties in the susceptor 300.

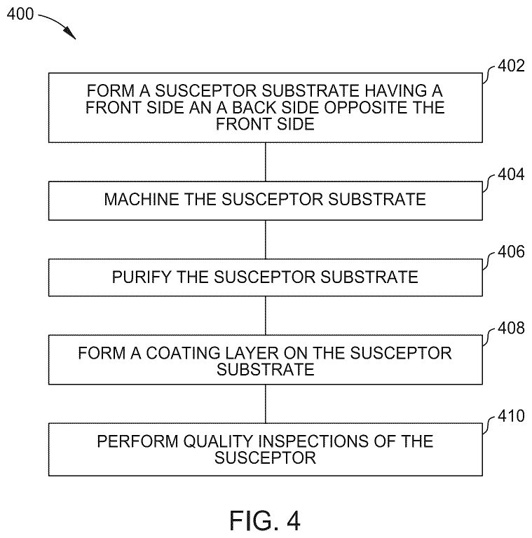

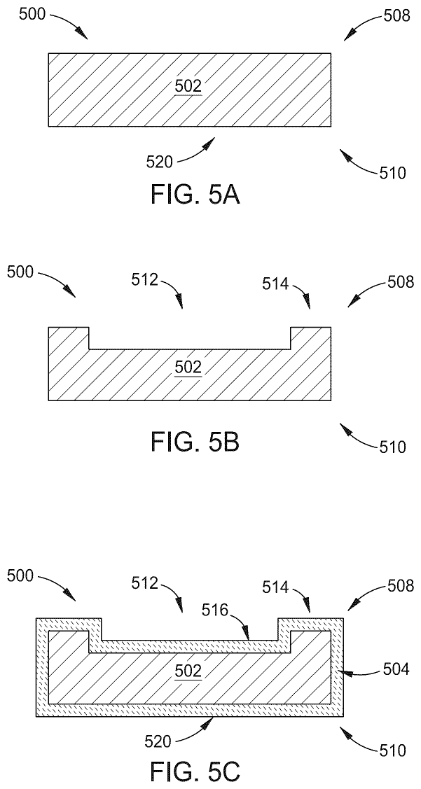

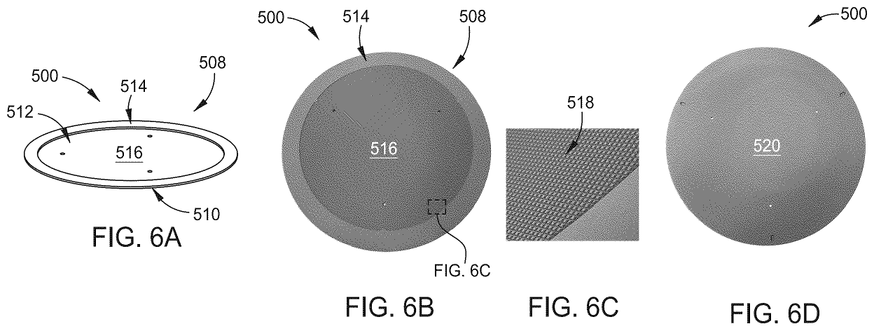

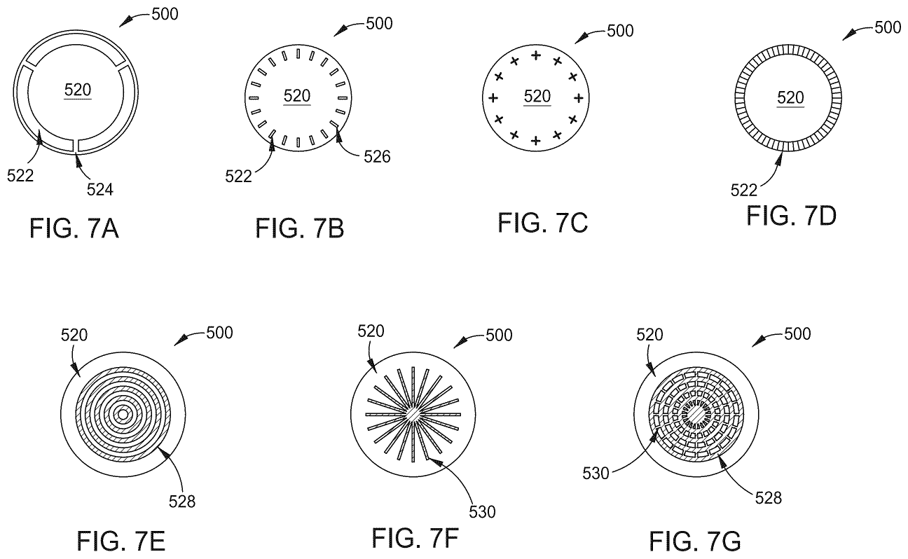

FIG. 4 is a flow diagram of a method 400 that may be utilized to manufacture a susceptor 500 having a front side 508 and a back side 510 opposite the front side 508, according to one embodiment. FIGS. 5A, 5B, and 5C are schematic cross-sectional views of a portion of the susceptor 500 corresponding to various stages of the method 400. FIGS. 6A, 6B, 6C, and 6D are an isometric view, a front view, an enlarged front view, and a back view of the susceptor 500 manufactured according to the method 400. FIGS. 7A, 7B, 7C, 7D, 7E, 7F, and 7G illustrate various patterns that may be applied to the back side 510 of the susceptor 500 according to the method 400. The susceptor 500 may be the susceptor 218 disposed in the processing chamber 200 from FIG. 2.

In block 402, a susceptor substrate 502 is formed. First, the susceptor substrate 502 is prepared by saw-cutting any suitable graphite billet into a disc-shaped plate and grinding surfaces of the disc-shaped plate, as shown in FIG. 5A. The susceptor substrate 502 may be formed of graphite having at least 99% purity. The susceptor substrate 502 may have a diameter of between about 150 mm and about 400 mm, for example, about 370 mm, and a thickness of between about 1 mm and about 15 mm, for example, about 3.70 mm.

In block 404, the susceptor substrate 502 may then be subjected to a surface treatment, such as precise machining for applying a specific surface structure to a surface of the susceptor substrate 502. The surface structure can be applied using conventional methods known in the art. During the surface treatment, a pocket 512 to hold a wafer (not shown) within a susceptor ledge 514 is formed on the front side 508 of the susceptor 500, as shown in FIG. 5B. The pocket 512 may be a cylindrical recess having a diameter of between about 150 mm and about 300 mm, for example, about 300 mm, and a depth of between about 0.30 mm and about 1.00 mm, for example, about 0.40 mm. The susceptor ledge 514 may have a width of between about 15 mm and about 70 mm, for example, about 35 mm. The back side 510 of the susceptor is machined to a flat and planar surface.

Subsequently, a surface 516 of the pocket 512 on the front side 508 is textured with a grid pattern 518 as shown in FIGS. 6B and 6C, by precise machining. The grid pattern 518 may have a width of between about 0.20 mm and about 3.00 mm, for example, about 0.43 mm, a pitch of between about 0.80 mm and about 3.00 mm, for example, about 1.14 mm, and a depth of between about 0.10 mm and about 5.00 mm, for example, about 0.31 mm.

In block 404, the back side 510 is also textured by precise machining. In some embodiments, a surface 520 of the back side 510 is uniformly textured with patterns. One example of the patterns is a grid pattern that matches with the grid pattern 518 applied to the surface 516 of the pocket 512 on the front side 508. Another example of the patterns is a stripe pattern, for example, having a width of between about 0.50 mm and about 30.00 mm, for example, about 3 mm, a pitch of between about 0.50 mm and about 3.00 mm, for example, about 0.8 mm, and a depth of between about 0.10 mm and about 5.00 mm, for example, about 0.3 mm. In some other embodiments, a ring pattern 522 is formed on an outer edge of the surface 520 of the back side 510. The ring pattern 522 may have a thickness of between about 0.10 mm and about 5.00 mm, for example, about 0.30 mm, and a width of between about 5.00 mm and about 50.00 mm, for example, about 35.00 mm. The width of the ring pattern 522 may be similar to the width of the susceptor ledge 514 on the front side 508 to compensate interfacial stress induced by the structural differences between the front side 508 and the back side 510. In one example, the ring pattern 522 includes cuts 524, as shown in FIG. 7A. The cuts 524 may have a width of between about 5 mm and about 45 mm, for example, about 30 mm, a length of between about 50 mm and about 120 mm, for example, about 100 mm. In another example, the ring pattern 522 is formed of an array of bar-shaped portions 526 disposed radially on the outer edge of the surface 520 of the back side 510, as shown in FIG. 7B. Each bar-shape portion 526 may have a length of between about 10 mm and about 50 mm, for example, about 30 mm, and a width of between about 0.50 mm and about 5.00 mm, for example, about 1.00 mm. The ring pattern 522 may include other shapes as shown in FIGS. 7C and 7D. In some other embodiments, multiple ring patterns 528, as shown in FIG. 7E, multiple radial line patterns 530, as shown in FIG. 7F, and a combination of the multiple ring patterns 528 and the multiple radial line patterns 530, as shown in FIG. 7G may be formed on the surface 520 of the back side 510. The multiple ring patterns 528 may each have a width of between about 1 mm and about 20 mm, for example, about 1.60 mm, a depth of between about 0.1 mm and about 5 mm, for example, about 0.30 mm, diameters varying between about 150 mm and about 300 mm, and a radial distance between adjacent ring patterns 528 of between about 1 mm and about 20 mm, for example, about 1.60 mm. The multiple radial line patterns 530 may each have a width of between about 1 mm and about 20 mm, for example, about 1.60 mm, a depth of between about 0.1 mm and 5 mm, for example, about 0.30 mm, a length of about 150 mm and about 300 mm, for example, about 300 mm, an angle between adjacent radial line patterns 530 of between about 0.5° and about 45°, for example, about 5°.

In block 406, the susceptor substrate 502 may subsequently be subjected to a purification treatment and a chlorination treatment. The susceptor substrate 502 may be heated in a furnace and purged with nitrogen gas at a temperature up about 2000° C. Chlorine gas is purged into the furnace to remove metal elements impurities from the susceptor substrate 502 by chlorinating carbonaceous materials such as graphite to remove metal element impurities. In the purification treatment and the chlorination treatment, an impurity level of the susceptor substrate 502 may be reduced below about 5 ppm.

In block 408, a coating layer 504 is formed on the susceptor substrate 502 by conformally depositing silicon carbide (SiC) on the susceptor substrate 502 by a CVD process. Silicon carbide (SiC) is deposited by using an organosilicon precursor. The coating layer 504 may have a thickness of between about 40 μm and about 300 μm, for example, about 80 μm.

In block 410, the susceptor 500 having the coating layer 504 on the susceptor substrate 502 is subsequently subjected to quality assurance (QA) inspections. Final dimensions of the susceptor 500 are determined by coordinate measuring machine (CMM) measurements by sensing discrete points on the surface of the susceptor 500.

The inventors observed warpage and bowing of a susceptor 500 of a thickness of about 3.70 mm with a flat and planar surface on the back side 510 manufactured according to blocks 402 to 410 of the method 400 described above (i.e., not including block 410 for texturing the back side 510 of the susceptor 500), and no reduction of warpage and bowing of susceptors 500 of a thickness of about 5.00 mm and of a thickness of about 6.35 mm, respectively, each with a flat and planar surface on the back side. The inventors observed about 75.5% reduction of warpage and bowing in a susceptor of a thickness of about 3.70 mm having the back side 510 textured with a grid pattern that matches with the grid pattern 518 applied to the surface 516 of the pocket 512 on the front side 508, and about 64.6% reduction of warpage and bowing in a susceptor 500 of a thickness of about 3.70 mm having the back side 510 textured with a stripe pattern, as compared to a susceptor 500 of a thickness of about 3.70 mm having a flat and planar surface on the back side 510.

In the embodiments described herein, a silicon carbide coated susceptor to hold a wafer thereon in an epitaxy deposition process has a back side thereof textured. Due to the textures on the back side of the susceptor, interfacial stress between a susceptor substrate and a coating layer is reduced during an epitaxy deposition process, reducing warping and bowing of the susceptor and increasing the flatness of the susceptor.

It should be noted that the particular configurations described above are among several possible example designs of a flat susceptor according to the present disclosure and do not limit the possible configurations, specifications, or the like of patterns according to the present disclosure. For example, textures on the back side of a susceptor are not limited to the patterns described above. In other examples, the back side of a susceptor may be textured with other patterns to reduce interfacial stress between the susceptor substrate and the coating layer caused during an epitaxial process.

While the foregoing is directed to specific embodiments, other and further embodiments may be devised without departing from the basic scope thereof, and the scope thereof is determined by the claims that follow.

1. A susceptor for use in a processing chamber for supporting a wafer, the susceptor comprising:
a susceptor substrate comprising graphite, and having a thickness of between 1 mm 15 mm; and
a coating layer deposited on the susceptor substrate, the coating layer comprising silicon-carbide (SiC) and having a thickness of between 40 μm and 300 μm, wherein
a front side of the susceptor substrate has a pocket configured to hold a wafer to be processed in a processing chamber, the pocket being textured with a first pattern, and
a back side of the susceptor substrate is textured with the first pattern.

2. The susceptor of claim 1, wherein the thickness of the susceptor substrate is about 6.35 mm.

3. The susceptor of claim 1, wherein the thickness of the susceptor substrate is about 3.7 mm.

4. The susceptor of claim 1, wherein the first pattern is a grid pattern having a depth of between 0.10 mm and 5.00 mm, a width of between 0.20 mm and 3.00 mm, and a pitch of between 0.80 mm and 3.00 mm.

5. The susceptor of claim 1, wherein the susceptor substrate is a disc-shaped plate having a diameter of between 150 mm and 400 mm.

6. The susceptor of claim 1, wherein the pocket is a cylindrical recess having a diameter of between 150 mm and 300 mm, and a depth of between 0.30 mm and 1.00 mm.

7. The susceptor of claim 1, wherein the susceptor substrate comprises porous graphite having pores into which silicon carbide (SiC) tendrils are formed.

8. A susceptor for use in a processing chamber for supporting a wafer, the susceptor comprising:
a susceptor substrate comprising graphite, and having a thickness of between 1 and 15 mm; and
a coating layer deposited on the susceptor substrate, the coating layer comprising silicon-carbide (SiC) and having a thickness of between 40 μm and 300 μm, wherein
a front side of the susceptor substrate has a pocket configured to hold a wafer to be processed in a processing chamber, the pocket being textured with a first pattern, and
a back side of the susceptor substrate is textured with a second pattern.

9. The susceptor of claim 8, wherein the thickness of the susceptor substrate is about 6.35 mm.

10. The susceptor of claim 8, wherein the first pattern is a grid pattern having a depth of between 0.10 mm and 5.00 mm, a width of between 0.20 mm and 3.00 mm, and a pitch of between 0.80 mm and 3.00 mm.

11. The susceptor of claim 8, wherein the second pattern is a stripe pattern having a depth of between 0.10 mm and 5.00 mm.

12. The susceptor of claim 11, wherein the stripe pattern has a width of between 0.50 mm and 30.00 mm, and a pitch of between 0.50 mm and 3.00 mm.

13. The susceptor of claim 8, wherein the susceptor substrate is a disc-shaped plate having a diameter of between 150 mm and 400 mm.

14. The susceptor of claim 8, wherein the pocket is a cylindrical recess having a diameter of between 150 mm and 300 mm, and a depth of between 0.30 mm and 1.00 mm.

15. The susceptor of claim 8, wherein the susceptor substrate comprises porous graphite having pores into which silicon carbide (SiC) tendrils are formed.
